(19) United States
(12) Patent Application Publication
(10) Pub. No.: US 2025/0139762 A1
(43) Pub. Date: May 1, 2025

(54) WAFER INSPECTION METHOD AND SEMICONDUCTOR DEVICE MANUFACTURING METHOD INCLUDING THE SAME

(71) Applicant: SAMSUNG ELECTRONICS CO., LTD., Suwon-si (KR)

(72) Inventors: Hyunchul KIM, Suwon-si (KR); Daewoong Choi, Suwon-si (KR); Ohchel Kwon, Suwon-si (KR); Hyunmo Kang, Suwon-si (KR); Taecheon Kim, Suwon-si (KR); Jinhong Park, Suwon-si (KR); Wooseok Choe, Suwon-si (KR)

(73) Assignee: SAMSUNG ELECTRONICS CO., LTD., Suwon-si (KR)

(21) Appl. No.: 18/890,365

(22) Filed: Sep. 19, 2024

(30) Foreign Application Priority Data
Oct. 25, 2023 (KR) 10-2023-0144176

(51) Int. Cl. G06T 7/00; H01L 21/66

(52) U.S. Cl. CPC G06T 7/001; H01L 22/12; G06T 2207/30148

(57) ABSTRACT

A wafer inspection method includes: obtaining an inspection image by capturing an image of a wafer and an identification tag; obtaining an inspection profile by quantifying the identification tag in the inspection image; and performing a surface inspection of the wafer based on the obtained inspection profile.

### CROSS-REFERENCE TO RELATED APPLICATION

This application is based on and claims priority under 35 U.S.C. § 119 to Korean Patent Application No. 10-2023-0144176, filed on Oct. 25, 2023, in the Korean Intellectual Property Office, the disclosure of which is incorporated by reference herein in its entirety.

### BACKGROUND

The disclosure relates to a wafer inspection method and a semiconductor device manufacturing method including the wafer inspection method. More particularly, the disclosure relates to a wafer inspection method in which a wafer surface is inspected by capturing an identification (ID) tag, and a semiconductor device manufacturing method including the wafer inspection method.

Generally, semiconductor devices are manufactured from a substrate such as a wafer. Specifically, semiconductor devices are manufactured by forming fine circuit patterns on an upper surface of the wafer by performing a deposition process, a photolithography process, or an etching process. To perform the semiconductor process on the wafer, a technique for determining whether foreign substances are present on the upper surface of the wafer on which the circuit patterns are formed may be required.

In addition, since the upper surface of the wafer (on which the circuit patterns are formed) may be contaminated with various foreign substances while performing the above processes, two processes may be required: a cleaning process to remove the foreign substances and a drying process after the cleaning process is performed. In the process of cleaning the wafer, organic compounds may be applied to the wafer, thus a technique for measuring the amount of the applied organic compounds may be required.

### SUMMARY

Provided are a wafer inspection method for inspecting a wafer surface with high reliability and a semiconductor device manufacturing method.

According to an aspect of the disclosure, a wafer inspection method includes: obtaining an inspection image by capturing an image of a wafer and an identification tag; obtaining an inspection profile by quantifying the identification tag in the inspection image; and performing a surface inspection of the wafer based on the obtained inspection profile.

According to an aspect of the disclosure, a wafer inspection method includes: obtaining a reference profile regarding a wafer by capturing a reference image and quantifying the reference image; obtaining an inspection profile regarding the wafer by capturing an inspection image and quantifying the inspection image; and performing a wafer surface inspection based on a difference between the reference profile and the inspection profile, wherein the reference image comprises a reference wafer and an identification tag, and wherein the inspection image includes an inspection target wafer and the identification tag, wherein the performing of the wafer surface inspection includes obtaining a profile of the wafer surface based on the difference between the reference profile and the inspection profile.

According to an aspect of the disclosure, a semiconductor device manufacturing method includes: preparing a wafer; performing a semiconductor process on the wafer; inspecting the wafer; and performing a subsequent semiconductor process on the wafer; wherein the inspecting the wafer includes: obtaining an inspection image by capturing an image of a wafer and an identification tag; obtaining an inspection profile by quantifying the identification tag in the inspection image; and performing a surface inspection of the wafer based on the obtained inspection profile.

### BRIEF DESCRIPTION OF THE DRAWINGS

Embodiments will be more clearly understood from the following detailed description taken in conjunction with the accompanying drawings in which:

FIG. 1 is a diagram of a wafer inspection device according to an embodiment;

FIG. 2 is a diagram of an identification tag according to an embodiment;

FIG. 3 is a flowchart of a wafer inspection method according to an embodiment;

FIG. 4 is a flowchart of a method of obtaining a reference profile, according to an embodiment;

FIG. 5 is a diagram of a reference image according to an embodiment;

FIG. 6 is a graph of a reference profile obtained by quantifying the reference image of FIG. 5;

FIG. 7 is a flowchart of a method of obtaining an inspection profile, according to an embodiment;

FIG. 8 is a diagram of an inspection image according to an embodiment;

FIG. 9 is a graph of a profile obtained by quantifying the inspection image of

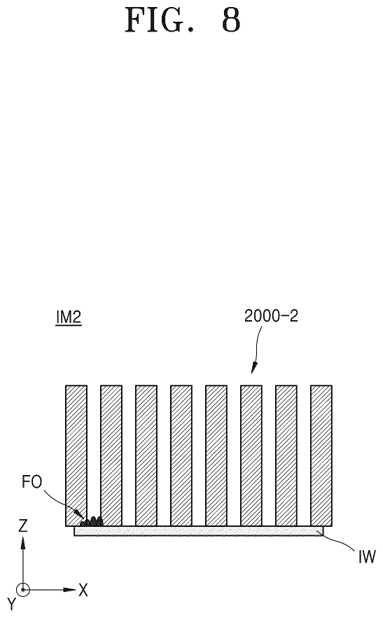

FIG. 8 according to an embodiment;

FIG. 10 is a graph of a surface profile of the wafer of FIG. 8;

FIG. 11 is a diagram of a wafer inspection device according to an embodiment;

FIG. 12 is a diagram of an inspection image according to an embodiment;

FIG. 13 is a graph of a profile obtained by quantifying the inspection image of

FIG. 12 according to an embodiment;

FIG. 14 is a graph of a surface profile of the wafer of FIG. 12;

FIG. 15 is a plan view of a wafer processing device according to an embodiment;

FIG. 16 is a flowchart of a semiconductor device manufacturing method using a wafer inspection method according to an embodiment; and

FIG. 17 is a schematic block diagram of a wafer inspection device according to an embodiment.

### DETAILED DESCRIPTION

Hereinafter, embodiments are described in detail with reference to the accompanying drawings. The same reference numerals are used for the same components in the drawings, and duplicate description thereof is omitted.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

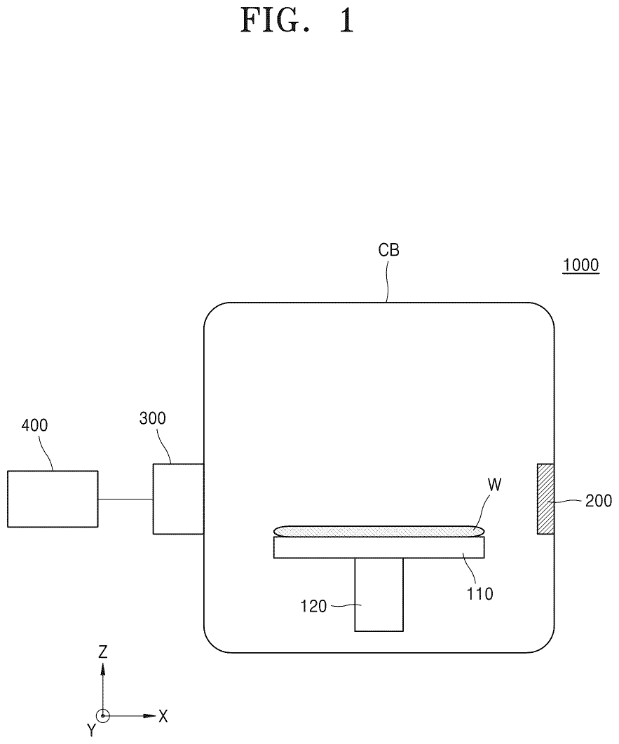

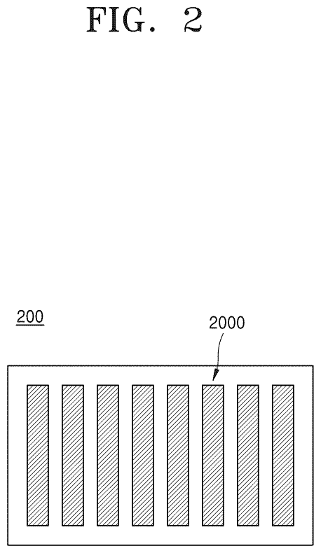

FIG. 1 is a diagram of a wafer inspection device according to an embodiment. FIG. 2 is a diagram of an identification tag according to an embodiment.

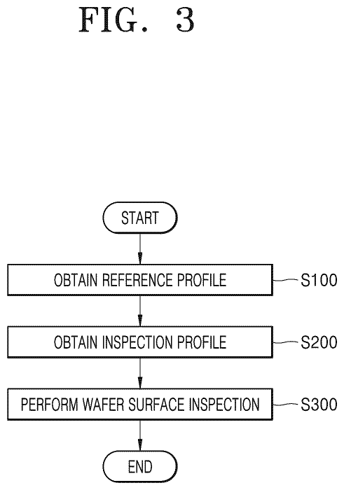

Referring to FIGS. 1 and 2, a wafer inspection device 1000 may include a process chamber CB, a chuck 110, a rotation driver 120, an identification tag 200, a camera 300, and a computer 400. The wafer inspection device 1000 may inspect a wafer W in an optical manner. The wafer inspection device 1000 may inspect a surface of the wafer W. A method of inspecting the wafer W by the wafer inspection device 1000 is described in detail with reference to FIGS. 3 to 14.

The process chamber CB may provide a processing area in which a semiconductor process is performed. The process chamber CB may include a housing forming the outer wall of the process chamber CB. The processing area may be inside the housing. A photo process, an etching process, a deposition process, or a cleaning process may be performed on the wafer W in the process chamber CB.

The chuck 110 may support the wafer W. The wafer W may be mounted on the chuck 110. The chuck 110 may be, for example, a vacuum chuck for fixing the wafer W with vacuum pressure, but is not limited thereto. For example, the chuck 110 may be an electrostatic chuck. The rotation driver 120 may rotate the chuck 110 to rotate the wafer W. The chuck 110 and the rotation driver 120 may be placed below the processing area provided by the process chamber CB.

The identification tag 200 may be placed on one surface of the housing (e.g., an inner wall) of the process chamber CB. In another embodiment, the identification tag 200 may be placed inside the process chamber CB and spaced apart from the housing. For example, the identification tag 200 may be placed in a shutter of the process chamber CB. The camera 300 may be configured to capture the identification tag 200. The identification tag 200 may include characters and/or figures. The identification tag 200 may function as a reference for inspecting the wafer W.

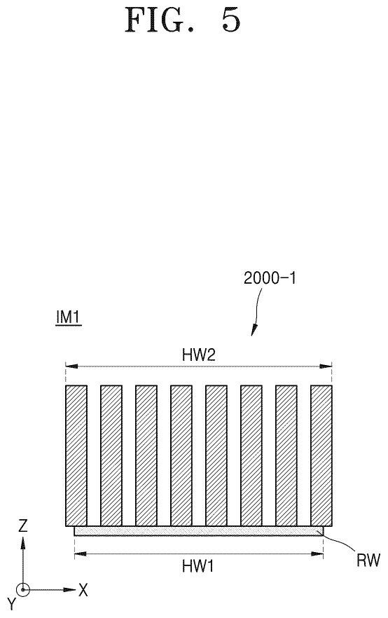

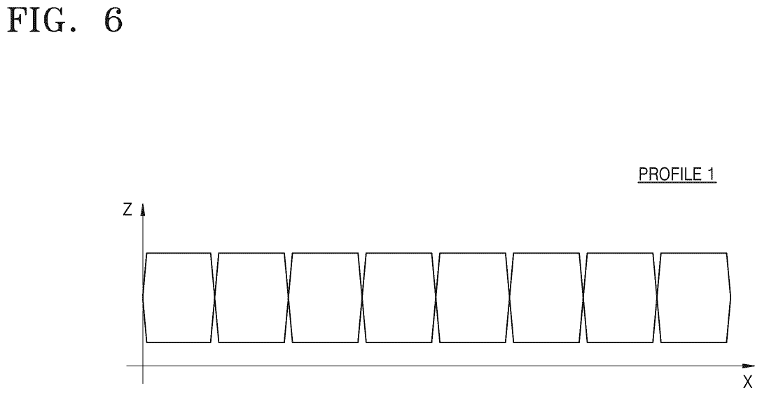

To perform inspection on an edge region of the wafer W with high reliability, a horizontal width (HW2 in FIG. 5) of the identification tag 200 may be greater than a horizontal width (HW1 in FIG. 5) of the wafer W. When the horizontal width (HW2 in FIG. 5) of the identification tag 200 is greater than the horizontal width (HW1 in FIG. 5) of the wafer W, FIGS. 2000 may be placed up to the edge region of the wafer W.

As an example, the identification tag 200 (shown in FIG. 2) includes a plurality of bar-shaped FIGS. 2000. Each of the plurality of bars may be spaced apart from each other. However, the identification tag 200 may have various shapes of figures. In addition, the identification tag 200 includes eight bar-shaped FIGS. 2000 in FIG. 2 as an example, but is not limited thereto. For example, the identification tag 200 may include 7 or less bar-shaped figures or may include 9 or more bar-shaped figures.

The camera 300 may capture the wafer W and the identification tag 200. The camera 300 may be placed outside the process chamber CB to capture the wafer W and the identification tag 200. For example, the camera 300 may be placed adjacent to a door of the process chamber CB to capture the wafer W and the identification tag 200. In another embodiment, the camera 300 may be placed inside the process chamber CB to capture the wafer W and the identification tag 200. In order for the camera 300 to capture the wafer W and the identification tag 200, the camera 300 and the identification tag 200 may be placed on opposite sides with respect to the wafer W. In addition, in order for the camera 300 to easily capture the wafer W and the identification tag 200, the identification tag 200 may be located at a higher vertical level than the wafer W.

The computer 400 may measure a surface of the wafer W based on an image (e.g., the identification tag 200) captured by the camera 300. The computer 400 may separate figures (e.g., the vertical bars of the identification tag 200, which are shown in FIG. 2) from the image captured by the camera 300. In addition, the computer 400 may quantify the figures to generate a profile. Then, the computer 400 may inspect the surface of the wafer W by comparing a reference profile with an inspection profile. The process of measuring the distribution of foreign substances (FO in FIG. 8) on the surface of the wafer W and the process of determining the distribution of chemical solution (C in FIG. 12) on the surface of the wafer W by the computer 400 are described in detail with reference to FIGS. 2 to 14.

The computer 400 may be implemented as hardware, firmware, software, or any combination thereof. For example, the computer 400 may be a computing device such as a workstation computer, a desktop computer, a laptop computer, a tablet computer, and the like. For example, the computer 400 may include a memory device, such as read only memory (ROM) and random access memory (RAM), and a processor configured to perform certain operations and algorithms, such as a microprocessor, a central processing unit (CPU), and a graphics processing unit (GPU). In addition, the computer 400 may include a receiver and a transmitter for receiving and transmitting electrical signals to components of the wafer inspection device 1000.

FIG. 3 is a flowchart of a wafer inspection method according to an embodiment. Descriptions are given with reference to FIG. 1 and FIG. 2.

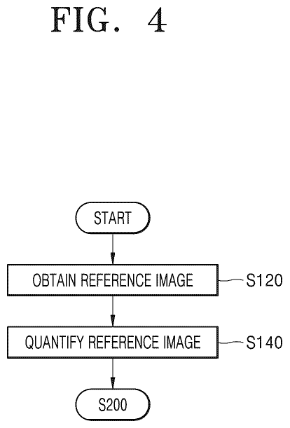

Referring to FIG. 3, first, a reference profile may be obtained (for example, by an electronic device) (S100). In some embodiments, the electronic device may correspond to the computer 400, a processor, or any external device. The reference profile may be a profile as a reference for inspecting the wafer W. The reference profile may include information on the surface of the wafer W for inspecting the wafer W. The reference profile may be measured based on a reference image. The process of obtaining the reference profile and the reference image is described in detail with reference to FIGS. 4 to 6.

FIG. 4 is a flowchart of a method of obtaining a reference profile, according to an embodiment. FIG. 5 is a diagram of a reference image according to an embodiment. FIG. 6 is a graph of a reference profile obtained by quantifying the reference image of FIG. 5. In FIG. 6, the horizontal axis represents X-direction coordinates and the vertical axis represents Z-direction coordinates. Descriptions are given with reference to FIGS. 1 to 3.

Referring to FIGS. 4 to 6, first, a reference image may be obtained (S120). The reference image may include an image of the identification tag 200 captured without loading the wafer W on the chuck 110 and/or an image of the identification tag 200 with the bare wafer W loaded on the chuck 110. In this disclosure, an image in which the identification tag 200 is captured with the bare wafer W loaded on the chuck 110 is illustrated, but is not limited thereto. The reference image may include a reference wafer RW and figures. The reference image may be referred to as a first image IM1. A wafer loaded on the chuck 110 to obtain the reference image IM1 may be referred to as the reference wafer RW. In addition, the FIGS. 2000 of the identification tag 200 captured in the reference image IM1 may be referred to as first FIGS. 2000-1.

The camera 300 may capture the reference wafer RW and the identification tag 200. As described above, in operation S100, the reference wafer RW may be a wafer W before the semiconductor process is performed. For example, in operation S100, the reference wafer RW may be a bare wafer. For example, when the wafer inspection method of the disclosure is used to evaluate a specific semiconductor process, the reference wafer RW may include a wafer W immediately before the semiconductor process is performed.

Thereafter, the reference image IM1 may be quantified (S140). The first FIGS. 2000-1 of the reference image IM1 may be quantified. More specifically, only the first FIGS. 2000-1 of the reference image IM1 may be quantified to show a profile of the first FIGS. 2000-1. The operation of quantifying the first FIGS. 2000-1 may include a process of dimensionally converting the size of a region (e.g., pixel) occupied by the first FIGS. 2000-1 of the reference image IM1 and showing the same on a graph. The computer 400 may quantify the first FIGS. 2000-1 of the reference image IM1.

In this disclosure, a direction parallel to a main surface of the wafer W may be defined as a horizontal direction (e.g., X direction, Y direction), and a direction perpendicular to the horizontal direction may be defined as a vertical direction (Z direction).

A first profile ‘PROFILE 1’ of FIG. 6 may include information corresponding to the first FIGS. 2000-1 of the reference image IM1. The first profile PROFILE 1 may include data corresponding to the position and the size of the first FIGS. 2000-1 of the reference image IM1.

As described above, the reference wafer RW, which is a subject of the reference image IM1, may not contain foreign substances on the surface thereof. Accordingly, the first FIGS. 2000-1 of the reference image IM1 may be maintained in the shape of the FIGS. 2000 of the identification tag 200. Accordingly, the first FIGS. 2000-1 of the reference image IM1 may have substantially the same shape as the FIGS. 2000 of the identification tag 200. The reference profile obtained by quantifying the reference image IM1 may include information on the shape of the FIGS. 2000 of the identification tag 200. The surface of the wafer W may be measured based on the reference profile. In another embodiment, the first FIGS. 2000-1 of the reference image IM1 may have a different shape from the FIGS. 2000 of the identification tag 200.

Returning to FIG. 3, the inspection profile may be obtained after operation S100 of obtaining the reference profile (S200). The inspection profile, which is conceptually similar to the reference profile, may include information on an inspection target wafer IW. For example, the inspection profile may include information on the surface of the inspection target wafer IW. The inspection profile may be measured from an image obtained by capturing the inspection target wafer IW (for example, by the camera 300) and the identification tag 200.

The reference wafer RW and the inspection target wafer IW are only classified for convenience of explanation, and both the reference wafer RW and the inspection target wafer IW may be wafers W. In some embodiments, the reference wafer RW may refer to a wafer W used to generate the reference profile, and the inspection target wafer IW may refer to a wafer W to be inspected.

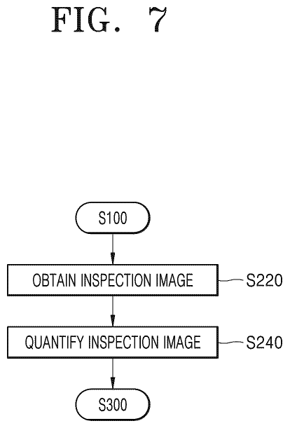

In FIG. 3, wafer surface inspection may be performed (S300). The surface inspection of the wafer W may be performed by calculating the difference between the reference profile and the inspection profile. By calculating the difference between the reference profile and the inspection profile, a wafer surface profile may be obtained. The wafer surface profile may include information on the surface of the wafer W. Obtaining the reference profile and performing the wafer surface inspection are described in more detail with reference to FIGS. 7 to 14. In some embodiments, the operations (S200 and S300) of FIG. 3 are also performed by an electronic device corresponding to the computer 400, a processor, and any external device.

FIG. 7 is a flowchart of a method of obtaining an inspection profile, according to an embodiment. Descriptions are given with reference to FIGS. 1 to 6. In some embodiments, the operations (S220 and S240) of FIG. 7 are performed by an electronic device corresponding to the computer 400, a processor, and any external device.

Referring to FIG. 7, first, an inspection image may be obtained (S220). The inspection image may include an image obtained by capturing the identification tag 200 with the inspection target wafer IW loaded on the chuck 110. The camera 300 may capture the inspection target wafer IW and the identification tag 200. Operation S220 may be substantially the same as operation S120 except that the inspection target wafer IW is captured.

Thereafter, the inspection image may be quantified (S240). For example, the figures captured in the inspection image may be quantified. In more detail, only the figures captured in the inspection image may be quantified to show the profile of the captured figures. The operation of quantifying the figures captured in the inspection image may include a process of dimensionally converting the size of the region (e.g., pixels) occupied by the figures captured in the inspection image onto a graph. Operation S240 may be substantially the same as operation S140, except that the figures captured in the inspection image are quantified.

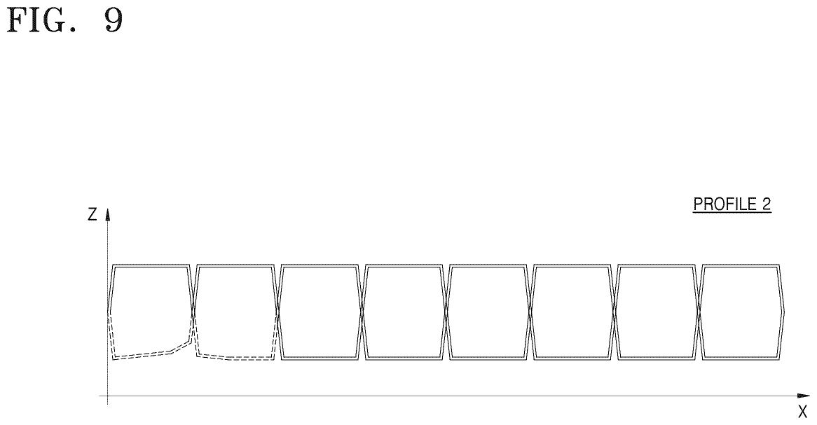

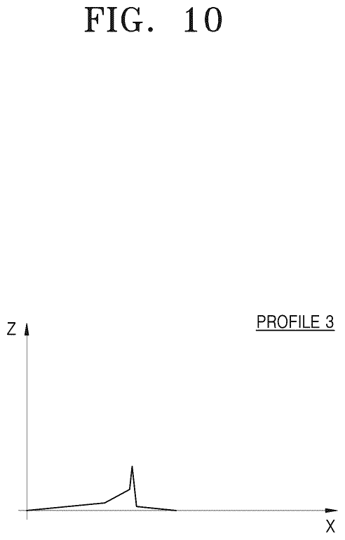

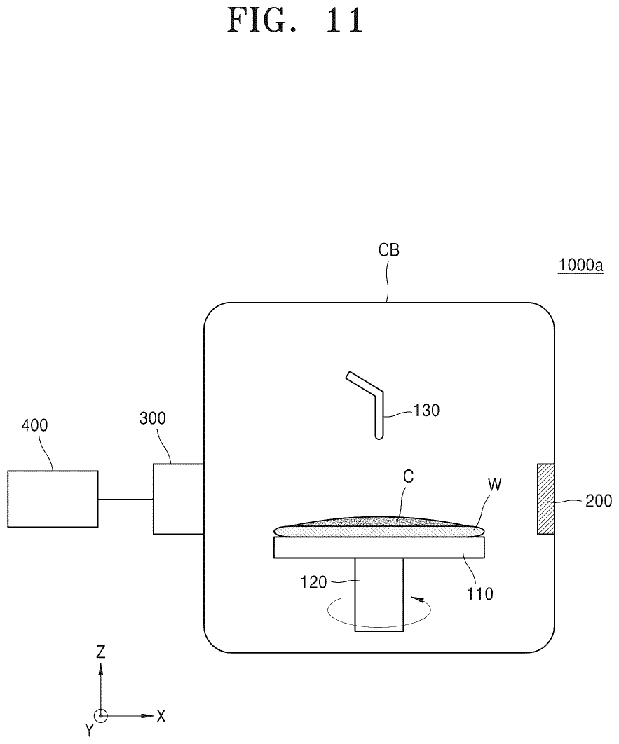

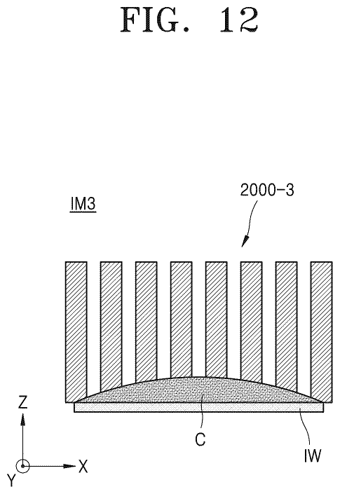

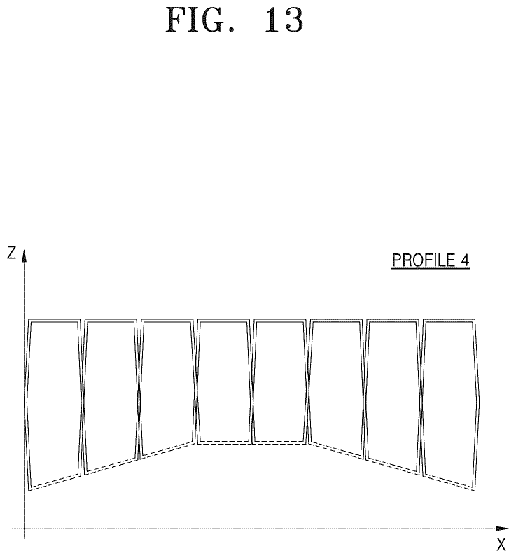

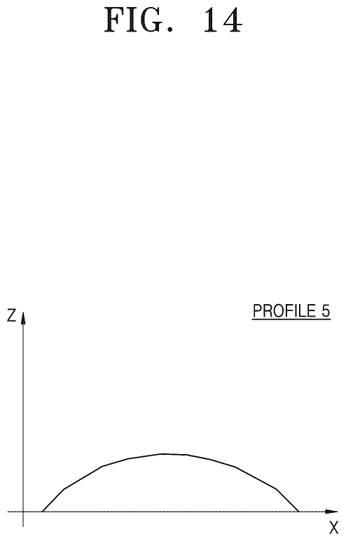

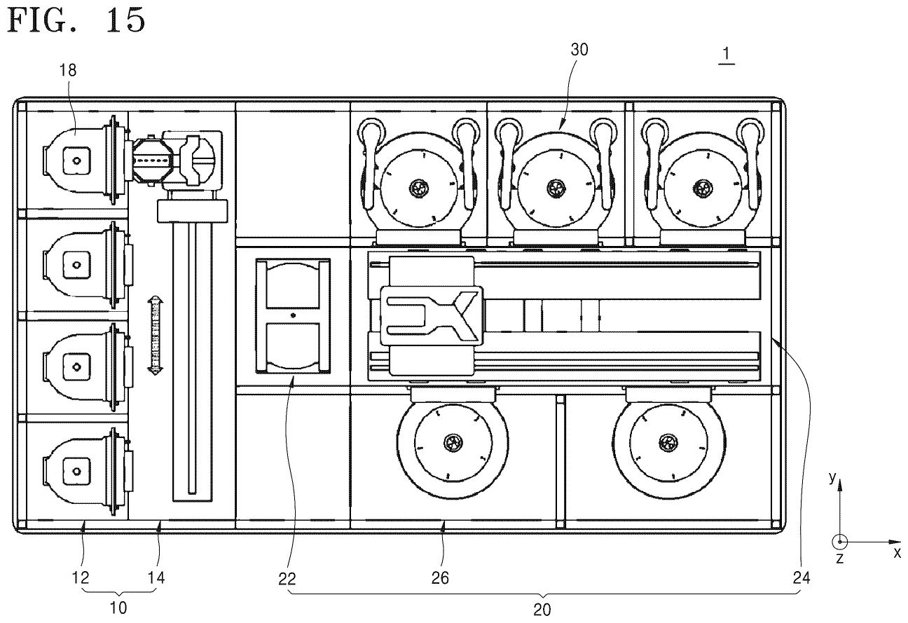

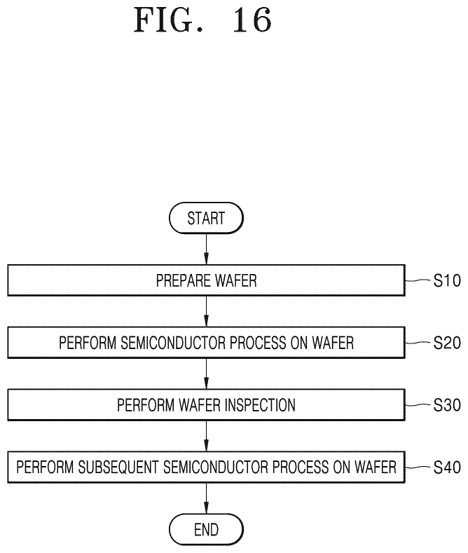

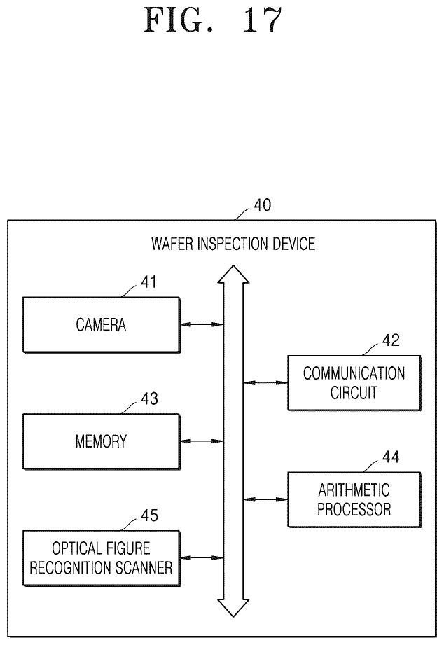

FIG. 8 is a diagram of an inspection image according to an embodiment. FIG. 9 is a graph of a profile obtained by quantifying the inspection image of FIG. 8 according to an embodiment. FIG. 10 is a graph of a surface profile of the wafer of FIG. 8. FIGS. 8 to 10 show an example case in which foreign substance FO is formed on the surface of the wafer W. In FIGS. 9 and 10, the horizontal axis represents X-direction coordinates and the vertical axis represents Z-direction coordinates. FIG. 10 shows an enlarged wafer surface profile. Descriptions are given with reference to FIGS. 6 and 7.

Referring to FIGS. 8 to 10, the inspection image may include an inspection target wafer IW and figures (e.g., vertical bars). The inspection image of FIG. 8 is referred to as a second image IM2, and the FIGS. 2000 of the identification tag 200 captured in the second image IM2 is referred to as second FIGS. 2000-2. The second image IM2 may include the inspection target wafer IW and the second FIGS. 2000-2. The inspection target wafer IW may include the foreign substance FO on the surface of the inspection target wafer IW. For example, the foreign substance FO may include or correspond to residue from the semiconductor process performed on the wafer W. Comparing the first image IM1 with the second image IM2, at least a portion of the second FIGS. 2000-2 in the second image IM2 may be obscured by overlap with the foreign substance FO. That is, on the second image IM2, the second FIGS. 2000-2 overlapping with the foreign substance FO may be obscured.

The second image IM2 may be quantified by performing operation S240 to obtain a profile of the second FIGS. 2000-2. More specifically, the second FIGS. 2000-2 of the second image IM2 may be quantified as shown in the graph of FIG. 9. In FIG. 9, the horizontal axis represents X-direction coordinates and the vertical axis represents Z-direction coordinates.

A second profile ‘PROFILE 2’ of FIG. 9 may include information corresponding to the second FIGS. 2000-2 of the second image IM2. The second profile PROFILE 2 may include data corresponding to the position and the size of the second FIGS. 2000-2 of the second image IM2.

As at least a portion of the FIGS. 2000 of the identification tag 200 is obscured in a region overlapping with the foreign substance FO in the second image IM2, the profile of the second FIGS. 2000-2 may also have a shape with a portion missing (as shown in FIG. 5 (dashed lines)), compared to the first profile PROFILE 1. In other words, the shape of the second profile PROFILE 2 of FIG. 9 may be different from that of the first profile PROFILE 1 of FIG. 6. In FIG. 9, a portion where the shape of the second profile PROFILE 2 is different from that of the first profile PROFILE 1 is shown by dashed lines. The portion may correspond to a position at which the foreign substance FO of the wafer W is formed. That is, by comparing the shape of the first profile PROFILE 1 with the shape of the second profile PROFILE 2, the difference therebetween may be determined, and the position and the size of the portion where the two profiles PROFILE 1 and PROFILE 2 are different may correspond to the position and the size of the foreign substance FO, respectively. That is, the surface inspection of the wafer W may be performed by comparing the first profile PROFILE 1 with the second profile PROFILE 2. More specifically, by excluding the region occupied by the second profile PROFILE 2 from the region occupied by the first profile PROFILE 1, the region occupied by the foreign substance FO may be measured. That is, by excluding the region occupied by the second profile PROFILE 2 from the region occupied by the first profile PROFILE 1, a surface profile of the inspection target wafer IW may be obtained. The surface profile of the inspection target wafer IW may be a profile of the foreign substance FO.

FIG. 10 shows an example of the wafer surface profile obtained by calculating the difference between the first profile PROFILE 1 and the second profile PROFILE 2. As described above, the wafer surface profile of FIG. 10 may be the profile of the foreign substance FO. The profile of FIG. 10 is referred to as a third profile PROFILE 3. FIG. 10 shows the profile of the foreign substance FO according to the position thereof. By comparing the first image IM1 with the second image IM2, the profile of the foreign substance FO formed on the wafer W may be obtained.

Through the method of FIGS. 8 to 10, the surface inspection of the wafer W may be performed. More specifically, through the method of FIGS. 8 to 10, the presence or absence of the foreign substance FO on the inspection target wafer W and the position thereof may be measured.

FIGS. 8 to 10 illustrate that the reference image IM1 is captured and then compared with the inspection image IM2, but embodiments of the disclosure are not limited thereto. In another embodiment, the reference image IM1 received from a library may be compared with the inspection image IM2 for inspecting the wafer W.

Next, a case is described where the wafer inspection method of the disclosure is used to evaluate the semiconductor process after the semiconductor process is performed. For example, a photo process, an etching process, a deposition process, and/or a cleaning process may be performed on the wafer W. FIGS. 11 to 15 show an example case in which the cleaning process is performed on the wafer W. However, embodiments of the disclosure are not limited thereto, and various semiconductor processes may be performed on the wafer W.

For example, the cleaning process may include or correspond to a process of cleaning an upper surface of the wafer W using organic compounds, and then supplying supercritical fluid to the upper surface of the wafer W to remove volatile organic compounds remaining on the upper surface of the wafer W.

FIG. 11 is a diagram of a wafer inspection device according to an embodiment. FIG. 11 shows an example case in which the chemical solution C is formed on the surface of the wafer. Descriptions are given with reference to FIG. 1.

Referring to FIG. 11, a wafer inspection device 1000a may include a process chamber CB, a chuck 110, a rotation driver 120, a dispenser 130, an identification tag 200, a camera 300, and an computer 400. The process chamber CB, the chuck 110, the rotation driver 120, the identification tag 200, the camera 300, and the computer 400 of the wafer inspection device 1000a of FIG. 11 may be substantially the same as those of FIG. 1, respectively.

The dispenser 130 may be configured to discharge the chemical solution Conto the wafer W. For example, the chemical solution C may include organic compounds. For example, the chemical solution C may include isopropyl alcohol (IPA). To effectively perform the cleaning process on the wafer, distribution of the chemical solution C on the wafer W needs to be monitored. To apply the chemical solution C onto the wafer W, the rotation driver 120 may rotate with respect to the rotation axis to rotate the chuck 110. The chemical solution C may be dispersed on the wafer W by the rotation of the rotation driver 120. The wafer inspection device 1000a may capture the wafer W and the identification tag 200 to quantitatively measure the distribution of the chemical solution C on the wafer W. The process of quantitatively measuring the distribution of the chemical solution C on the wafer W by the wafer inspection device 1000a is described in more detail with reference to FIGS. 12 to 14.

FIG. 12 is a diagram of an inspection image according to an embodiment. FIG. 13 is a graph of a profile obtained by quantifying the inspection image of FIG. 12 according to an embodiment. FIG. 14 is a graph of a surface profile of the wafer of FIG. 12. FIGS. 12 to 14 shows an example case in which the chemical solution C is formed on the surface of the wafer W. In FIGS. 13 and 14, the horizontal axis represents X-direction coordinates and the vertical axis represents Z-direction coordinates. Descriptions are given with reference to FIGS. 4 to 10.

Referring to FIGS. 12 to 14, the inspection image may include the inspection target wafer IW, the chemical solution C, and the figures (e.g., the vertical bars). The inspection image of FIG. 12 is referred to as a third image IM3, and the FIGS. 2000 of the identification tag 200 captured in the third image IM3 are referred to as third FIGS. 2000-3. The third image IM3 may include images of the inspection target wafer IW, the chemical solution C, and the third FIGS. 2000-3, for example, captured by the camera 300. Comparing the first image IM1 with the third image IM3, at least a portion of the third FIGS. 2000-3 in the third image IM3 may be obscured by overlapping with the chemical solution C. That is, in the third image IM3, the FIGS. 2000 of the identification tag 200 overlapping with the chemical solution C may be omitted.

The third image IM3 may be quantified by performing operation S240 to obtain a profile of the third FIGS. 2000-3. More specifically, the third FIGS. 2000-3 of the third image IM3 may be quantified as shown in the graph of FIG. 13.

A fourth profile PROFILE 4 of FIG. 13 may include information corresponding to the third FIGS. 2000-3 of the third image IM3. The fourth profile PROFILE 4 may include data corresponding to the position and the size of the third FIGS. 2000-3 of the third image IM3.

In the third image IM3, at least a portion of the FIGS. 2000 of the identification tag 200 is obscured in the region overlapping with the chemical solution C, and the profile of the third FIGS. 2000-3 may also have a shape with a portion missing, compared to the first profile PROFILE 1. The shape of the fourth profile PROFILE 4 of FIG. 13 may be different from that of the first profile PROFILE 1 of FIG. 6. In FIG. 13, a portion where the shape of the second profile PROFILE 2 is different from that of the first profile PROFILE 1 is shown by a dashed line. The portion may correspond to the position where the chemical solution C is formed. That is, the surface inspection of the wafer W may be performed by comparing the first profile PROFILE 1 with the fourth profile PROFILE 4. More specifically, the region occupied by the chemical solution C may be measured by excluding the region occupied by the fourth profile PROFILE 4 from the region occupied by the first profile PROFILE 1. That is, the surface profile of the inspection target wafer IW may be obtained by excluding the region occupied by the fourth profile PROFILE 4 from the region occupied by the first profile PROFILE 1. The surface profile of the inspection target wafer IW may be a profile of the chemical solution C.

FIG. 14 shows an example of the wafer surface profile obtained by calculating the difference between the first profile PROFILE 1 and the fourth profile PROFILE 4. As described above, the wafer surface profile of FIG. 14 may be the profile of the chemical solution C. The profile of FIG. 14 is referred to as a fifth profile PROFILE 5. FIG. 14 shows the profile of the chemical solution C according to the position thereof. By comparing the first image IM1 with the third image IM3, the profile of the chemical solution C formed on the wafer W may be obtained.

After the distribution of the chemical solution C is measured on the wafer W, it may be determined (for example, by an electronic device corresponding to the computer 400, a processor, or any external device) whether the chemical solution C is evenly distributed on the wafer W by comparing the distribution of reference chemical solution C with the distribution of the measured chemical solution C. The distribution of the reference chemical solution C may be a reference for determining whether the distribution of the chemical solution C formed on the wafer W is normal. When the similarity rate between the distribution of the reference chemical solution C and the distribution of the measured chemical solution C is less than or equal to a threshold value, the distribution of the chemical solution C on the wafer W may be determined to be abnormal. Conversely, when the similarity rate between the distribution of the reference chemical solution C and the distribution of the measured chemical solution C is greater than or equal to a threshold value, the distribution of the chemical solution C on the wafer W may be determined to be normal.

FIGS. 11 to 14 illustrate that the reference image IM1 is captured and then compared with the inspection image IM3, but embodiments of the disclosure are not limited thereto. In another embodiment, the reference image IM1 received from a library may be compared with the inspection image IM3 for inspecting the wafer W.

According to embodiments of the disclosure, the wafer inspection devices 1000 and 1000a and the wafer inspection method have been described above with reference to FIGS. 1 to 14. In related art, conventional wafer inspection devices and wafer inspection methods required various optical devices that generate light reflection and/or interference phenomena since wafers are inspected using the light reflection and/or interference phenomena. In addition, a method of inspecting a wafer in real time during a semiconductor process has not been disclosed for conventional wafer inspection devices and wafer inspection methods.

On the other hand, the wafer inspection devices 1000 and 1000a and the wafer inspection method of the disclosure may capture the identification tag 200 and easily perform the wafer inspection. In addition, the wafer inspection devices 1000 and 1000a and the wafer inspection method of the disclosure do not require optical devices that generate light reflection and/or interference phenomena, and may perform wafer W inspection in real time during the semiconductor process. Accordingly, the wafer inspection devices 1000 and 1000a and the wafer inspection method may be highly reliable.

FIG. 15 is a plan view of a wafer processing device according to an embodiment. FIG. 15 shows a wafer processing device including a wafer cleaning device 30. Descriptions are given with reference to FIG. 1.

Referring to FIG. 15, the wafer processing device 1 may include an index module 10 and a process processing module 20. The index module 10 may include a load port 12 and a transfer frame 14. In some embodiments, the load port 12, the transfer frame 14, and the process processing module 20 may be sequentially placed in a row.

A carrier 18 (in which the wafer W is housed) may be seated on the load port 12. For example, the carrier 18 may include a front opening unified pod (FOUP). A plurality of load ports 12 may be provided. The number of load ports 12 may increase or decrease depending on the process efficiency and the footprint condition of the process processing module 20. A plurality of slots are formed in the carrier 18 to accommodate the wafers W, arranged horizontally with respect to the ground.

The process processing module 20 may include a buffer 22, a transfer chamber 24, and process chambers 26. The process chambers 26 may be placed on both sides of the transfer chamber 24. The process chambers 26 on one side and the other side of the transfer chamber 24 may be provided to be symmetrical to each other with respect to the transfer chamber 24.

Some of the process chambers 26 are placed in the longitudinal direction of the transfer chamber 24. In addition, some of the process chambers 26 are stacked on top of each other. That is, the process chambers 26 may be placed in an arrangement of A x B (A and B are natural numbers) on one side of the transfer chamber 24. “A” is a number of process chambers 26 provided in a row in the first horizontal direction (X direction). “B” is a number of process chambers 26 provided in a row in the second horizontal direction (Y direction). When four or six process chambers 26 are provided on both sides of the transfer chamber 24, the process chambers 26 may be arranged in a 2×2 or 3×2 arrangement. The number of process chambers 26 may increase or decrease. In some embodiments, the process chamber 26 may be provided only on one side of the transfer chamber 24. Additionally, in some embodiments, the process chambers 26 may be provided as a single layer on one side and both sides of the transfer chamber 24.

The buffer 22 is placed between the transfer frame 14 and the transfer chamber 24. The buffer 22 provides an area for the wafer W to stay before the wafer W is transferred between the process chamber 26 and the carrier 18. The transfer frame 14 transfers the wafer W between the carrier 18 seated on the load port 12 and the buffer 22.

The transfer chamber 24 transfers the wafer W between the buffer 22 and the process chamber 26 and between the process chambers 26. The wafer cleaning device 30 that performs a cleaning process on the wafer W is provided in the process chamber 26. The wafer cleaning device 30 may have a different structure depending on the type of cleaning process to be performed.

FIG. 16 is a flowchart of a semiconductor device manufacturing method using a wafer inspection method according to an embodiment. Descriptions are given with reference to FIGS. 1 to 15.

Referring to FIG. 16, first, a wafer W may be prepared (S10). The wafer W may include, for example, a wafer on which one or more semiconductor processes are performed or a bare wafer on which any semiconductor process is not performed.

Thereafter, a semiconductor process may be performed on the wafer W (S20). An oxidation process, a photo process, a deposition process, an etching process, an ion process, and/or a cleaning process may be performed on the wafer W.

Thereafter, wafer W inspection may be performed (S30). The operation of performing the wafer W inspection may include operation S100 of obtaining the reference profile of FIG. 3, operation S200 of obtaining the inspection profile, and operation S300 of performing surface inspection of the wafer W. In addition, operation S100 of obtaining the reference profile may include operation S120 of obtaining the reference image IM1 and operation S140 of quantifying the reference image IR1. In addition, operation S200 of obtaining the inspection profile may include operation S220 of obtaining the inspection image IM2 and IM3 and operation S240 of quantifying the inspection images IM2 and IM3. Operation S30 of performing wafer W inspection may include an operation of evaluating the surface of the wafer W and/or an operation of evaluating the semiconductor process performed in operation S20.

Thereafter, a subsequent semiconductor process is performed on the wafer W (S40). The subsequent semiconductor process on the wafer W may include various processes. For example, the subsequent semiconductor process may include an oxidation process, a photo process, a deposition process, an etching process, an ion process, and/or a cleaning process, etc. In addition, the subsequent semiconductor process may include a singulation process of individualizing the wafer W into each semiconductor chip, a test process of testing the semiconductor chips, and a packaging process of packaging the semiconductor chips. A semiconductor device may be completed through the subsequent semiconductor process on the wafer W.

FIG. 17 is a schematic block diagram of a wafer inspection device according to an embodiment. Descriptions are given with reference to FIGS. 1 to 16.

Referring to FIG. 17, a wafer inspection device 40 may include a camera 41, a communication circuit 42, memory 43, an arithmetic processor 44, and an optical figure recognition scanner 45. However, components included in the wafer inspection device 40 are not necessarily limited thereto, and the wafer inspecting device 40 may include other components for inspecting the wafer W.

According to an embodiment, the camera 41 may be configured to capture the wafer W and the identification tag 200. The communication circuit 42 may provide network communication to the wafer inspection device 40. The network may include a wired network, such as a radio network, a cellular network, a satellite network, a broadcast network, or a wireless network. In an embodiment, the wafer inspection device 40 may be an electrical device, such as a computer, a smartphone, a personal computer, or a server, in which an image processing program is installed.

According to an embodiment, the optical figure recognition scanner 45 may recognize the identification tag 200 (e.g., captured by the camera 41) as figures. The arithmetic processor 44 may quantify the recognized figures to generate an inspection profile. In addition, the arithmetic processor 44 may compare the inspection profile with the reference profile stored in the memory 43 and/or the reference profile generated by quantifying the reference image captured by the camera 41 to determine whether the wafer is defective or not.

According to an embodiment, the memory 43 may include, for example, flash memory, a hard disk drive (HDD), a solid state drive (SSD), dynamic random-access memory (DRAM), static random-Access memory (SRAM), and the like. For example, the arithmetic processor 44 may include a CPU, a GPU, a vector processor, a quantum arithmetic processor, an embedded arithmetic processor, and the like. For example, the optical figure recognition scanner 45 may include an image scanner.

While the disclosure has been particularly shown and described with reference to embodiments thereof, various changes in form and details may be made therein without departing from the spirit and scope of the following claims.

What is claimed is:

1. A wafer inspection method comprising:
obtaining an inspection image by capturing an image of a wafer and an identification tag;
obtaining an inspection profile by quantifying the identification tag in the inspection image; and
performing a surface inspection of the wafer based on the obtained inspection profile.

2. The wafer inspection method of claim 1, wherein the identification tag comprises at least one of a character and a figure.

3. The wafer inspection method of claim 1, wherein the identification tag comprises a plurality of bar-shaped figures.

4. The wafer inspection method of claim 2, wherein the obtaining the inspection profile comprises quantifying at least one of the character and the figure included in the identification tag in the inspection image.

5. The wafer inspection method of claim 1, further comprising obtaining a reference profile that is a reference for the surface inspection of the wafer.

6. The wafer inspection method of claim 5, wherein the performing the surface inspection of the wafer comprises obtaining a profile of the wafer surface, based on a difference between the reference profile and the inspection profile.

7. The wafer inspection method of claim 1, wherein a first horizontal width of the identification tag is greater than a second horizontal width of the wafer.

8. A wafer inspection method comprising:
obtaining a reference profile regarding a wafer by capturing a reference image and quantifying the reference image;
obtaining an inspection profile regarding the wafer by capturing an inspection image and quantifying the inspection image; and
performing a wafer surface inspection based on a difference between the reference profile and the inspection profile,
wherein the reference image comprises a reference wafer and an identification tag, and
wherein the inspection image comprises an inspection target wafer and the identification tag, and
wherein the performing of the wafer surface inspection comprises obtaining a profile of the wafer surface based on the difference between the reference profile and the inspection profile.

9. The wafer inspection method of claim 8, wherein the obtaining the reference profile comprises quantifying a first region occupied by the identification tag included in the reference image, and
wherein the obtaining the inspection profile comprises quantifying a second region occupied by the identification tag in the inspection image.

10. The wafer inspection method of claim 8, wherein the profile of the wafer surface comprises information on at least one of a foreign substance and a chemical solution on the wafer.

11. The wafer inspection method of claim 10, wherein at least a portion of the identification tag in the inspection image is obscured by at least one of the foreign substance and the chemical solution on the wafer.

12. The wafer inspection method of claim 8, wherein the performing the wafer surface inspection comprises comparing a measured profile of the wafer surface with a reference wafer surface profile.

13. The wafer inspection method of claim 12, further comprising, when a difference between the measured profile of the wafer surface and the reference wafer surface profile is greater than a preset threshold value, determining that the inspection target wafer is defective, and
when the difference between the measured profile of the wafer surface and the reference wafer surface profile is less than the preset threshold value, determining that the inspection target wafer is normal.

14. The wafer inspection method of claim 8, wherein the identification tag is located at a vertical level higher than the wafer.

15. The wafer inspection method of claim 8, wherein a first horizontal width of the identification tag is greater than a second horizontal width of the wafer.

16. The wafer inspection method of claim 8, wherein the reference wafer comprises a bare wafer.

17. A semiconductor device manufacturing method comprising:
preparing a wafer;
performing a semiconductor process on the wafer;
inspecting the wafer; and
performing a subsequent semiconductor process on the wafer;
wherein the inspecting the wafer comprises:
obtaining an inspection image by capturing an image of a wafer and an identification tag;
obtaining an inspection profile by quantifying the identification tag in the inspection image; and
performing a surface inspection of the wafer based on the obtained inspection profile.

18. The semiconductor device manufacturing method of claim 17, wherein the inspecting the wafer comprises:
obtaining a reference profile for the surface inspection of the wafer; and
obtaining a surface profile of the wafer, based on a difference between the reference profile and the inspection profile.

19. The semiconductor device manufacturing method of claim 18, wherein the reference profile is obtained by quantifying a reference image obtained by capturing a reference wafer and the identification tag.

20. The semiconductor device manufacturing method of claim 17, wherein the performing the semiconductor process on the wafer comprises:
applying a chemical solution on the wafer; and
dispersing the chemical solution by rotating the wafer, and
wherein the inspecting the wafer comprises inspecting a distribution of the chemical solution on the wafer.
